(19) United States
(12) Patent Application Publication
(10) Pub. No.: US 2024/0072156 A1
(43) Pub. Date: Feb. 29, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chen-Huang Huang, Chiayi County (TW); An Chyi Wei, Hsin-Chu City (TW); Ryan Chia-Jen Chen, Hsinchu (TW); Hsuan-Chih Wu, Taoyuan City (TW)

(73) Assignee: Taiwan Semiconductor Manufacturing Company, Ltd., Hsinchu (TW)

(21) Appl. No.: 17/894,169

(22) Filed: Aug. 24, 2022

(51) Int. Cl. H01L 29/66; H01L 21/02; H01L 21/311; H01L 27/088; H01L 29/06; H01L 29/423; H01L 29/49; H01L 29/775; H01L 29/786

(52) U.S. Cl. CPC H01L 29/6653; H01L 21/0206; H01L 21/02532; H01L 21/02603; H01L 21/31116; H01L 27/088; H01L 29/0673; H01L 29/42392; H01L 29/4983; H01L 29/66439; H01L 29/66545; H01L 29/66742; H01L 29/775; H01L 29/78696

(57) ABSTRACT

A semiconductor device structure and a manufacturing method thereof are provided. The semiconductor device structure includes a semiconductor substrate, semiconductor channel sheets disposed over the semiconductor substrate, and source and drain regions located beside the semiconductor channel sheets. A gate structure is disposed between the source and drain regions and disposed over the semiconductor channel sheets. The gate structure laterally surrounds the semiconductor channel sheets. The gate structure includes a top gate electrode structure disposed above the semiconductor channel sheets, and lower gate electrode structures disposed between the semiconductor channel sheets. Sidewall spacers are disposed between the gate structure and source and drain regions, and the sidewall spacers located next to the top gate electrode structure have slant sidewalls.

### BACKGROUND

In the manufacturing processes of integrated circuits, electronic circuits with components such as transistors are formed from semiconductor-based wafers. Continuously scaling down and high integration density of semiconductor devices have increased the complexity of semiconductor manufacturing processes.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 10 are schematic views of various stages in a manufacturing method of a semiconductor device in accordance with some embodiments of the disclosure.

FIG. 11 is a schematic cross-sectional view of portions of semiconductor devices in different regions in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure. Source/drain region(s) may refer to a source or a drain, individually or collectively dependent upon the context.

It should be appreciated that the following embodiment(s) of the present disclosure provides applicable concepts that can be embodied in a wide variety of specific contexts. The embodiments are intended to provide further explanations but are not used to limit the scope of the present disclosure. The specific embodiment(s) described herein is related to a structure containing one or more semiconductor devices, and is not intended to limit the scope of the present disclosure. Embodiments of the present disclosure describe the exemplary manufacturing process of the structure(s) formed with one or more semiconductor devices such as transistors and the integrated structures fabricated there-from. Certain embodiments of the present disclosure are related to the structures including semiconductor transistors and/or other elements. The substrates and/or wafers may include one or more types of integrated circuits or electronic components therein. The semiconductor device(s) may be formed on a bulk semiconductor substrate or a silicon/germanium-on-insulator substrate.

The present disclosure describes semiconductor devices, such as field-effect transistors (FETs), such as planar FETs, fin-type FETs (FinFETs), or gate all around (GAA) transistors.

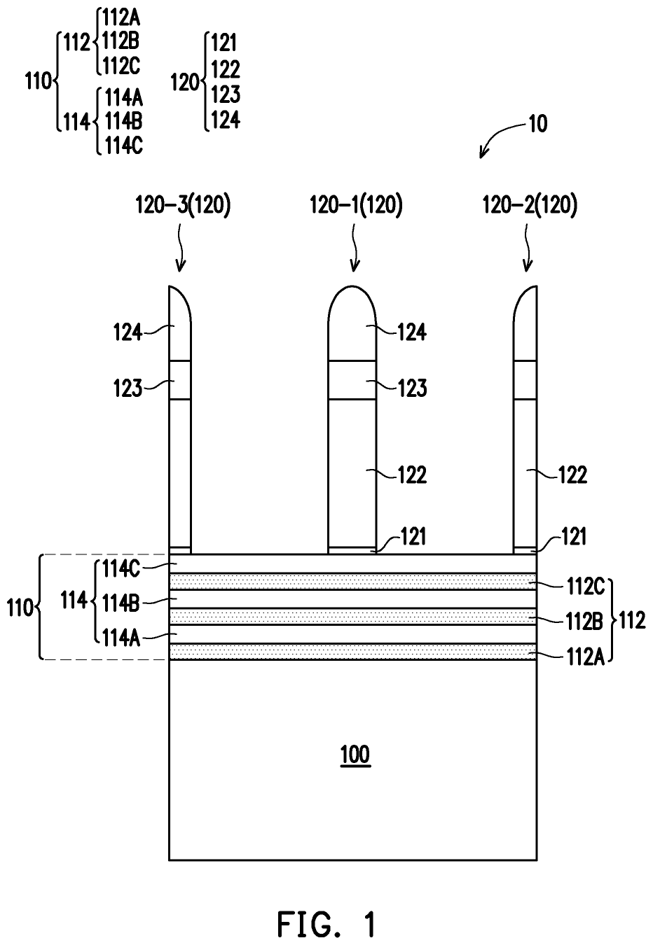

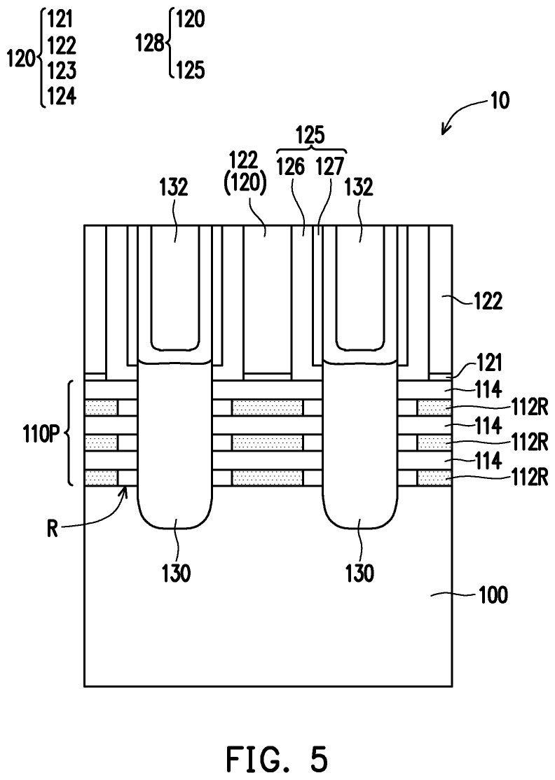

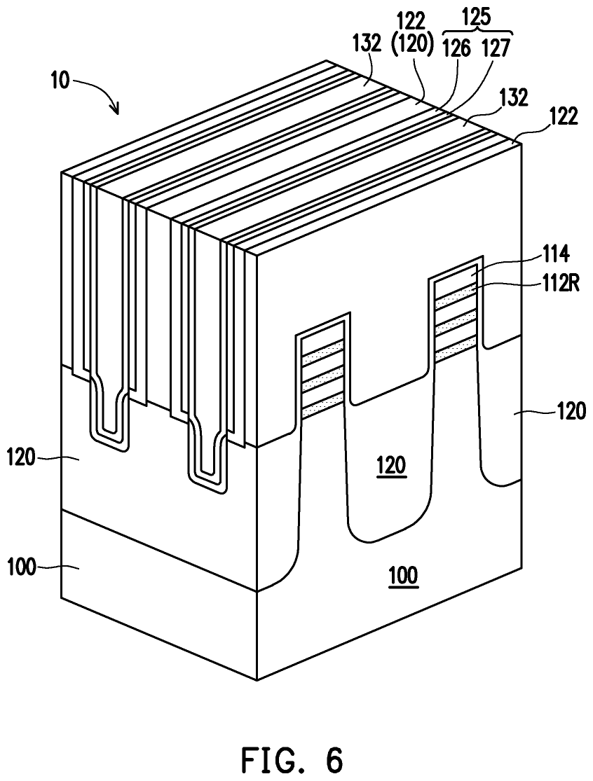

FIG. 1 to FIG. 10 are schematic views of various stages in a manufacturing method of semiconductor devices in accordance with some embodiments of the disclosure. From FIG. 1 through FIG. 5 and FIG. 7 through FIG. 10, schematic cross-section views of one or more semiconductor devices in a device region of the structure at successive intermediate stages of processing are shown, while an exemplary schematic 3D view of FIG. 5 is shown in FIG. 6 for illustration purpose. Particularly, FIG. 1 to FIG. 10 illustrate exemplary manufacturing processes for forming gate all around (GAA) transistors. Other process steps and combinations of process steps can be utilized without departing from the scope of the present disclosure.

Referring to FIG. 1, in some embodiments, a substrate 100 having stacks of multiple sheets (fin stacks) 110 is provided. From FIG. 1 to FIG. 10, only a portion of the device region of the structure 10 is shown for illustration purposes. It is understood that only one fin stack is shown in FIG. 1, but multiple fin stacks are formed over the substrate 100.

Referring to FIG. 1, in some embodiments, the substrate 100 includes a semiconductor substrate. In one embodiment, the substrate 100 comprises a bulk semiconductor substrate such as a crystalline silicon substrate, and may be doped (e.g., p-type or n-type semiconductor substrate) or undoped. In one embodiment, the substrate 100 comprises a silicon-on-insulator substrate or a germanium-on-insulator substrate. In certain embodiments, the substrate 100 includes one or more doped regions or various types of doped regions, depending on design requirements. In some embodiments, the doped regions are doped with p-type and/or n-type dopants. For example, the p-type dopants are boron, indium, aluminum, or gallium, and the n-type dopants are phosphorus or arsenic. In some embodiments, the substrate 100 includes a semiconductor substrate made of other suitable elemental semiconductor, such as diamond or germanium; a suitable compound semiconductor, such as gallium arsenide (GaAs), silicon carbide (SiC), indium arsenide (InAs), or indium phosphide (InP); or a suitable alloy semiconductor, such as silicon-germanium (SiGe), gallium arsenic phosphide (GaAsP), or gallium indium phosphide (GaInP). In some embodiments, the substrate 100 includes an oxide semiconductor material such as indium tin oxide (ITO). It is understood that different types of substrates, such as single-layer, multi-layered, or gradient substrates may be used.

In FIG. 1, only one fin stack is shown in some embodiments, the fin stack 110 includes alternating layers of first semiconductor layers 112A-112C (collectively referred to as first semiconductor layers 112) and second semiconductor layers 114A-114C (collectively referred to as second semiconductor layers 114). In some embodiments, the first semiconductor layers 112 is formed of a first semiconductor material, the second semiconductor layers 114 is formed of a second semiconductor material, and the second semiconductor material is different from the first semiconductor material. For example, the first or second semiconductor material may include one or more selected from silicon, germanium, SiC, SiGe, GaAs, InSb, GaP, GaSb, InAlAs, InGaAs, GaSbP, GaAsSb or InP. In some embodiments, the first semiconductor layers 112 may include silicon germanium (SiGe) or the like, and the second semiconductor layers 114 may include silicon, silicon carbide, or the like. In at least one embodiment, second semiconductor layers 114 are of the same semiconductor material as the substrate 100. In a non-limiting example described herein, the second semiconductor layers 114 and the substrate 100 include silicon. In one embodiment, the first semiconductor layers 112 include SiGe, while the second semiconductor layers 114 include silicon or silicon carbide.

For example, the fin stack 110 may be formed by performing alternating epitaxial growth processes, including performing first epitaxial growth processes to form first semiconductor material layers (not shown) and performing second epitaxial growth processes to form second semiconductor material layers (not shown) in alternation, and then patterning the first and second semiconductor material layers into the first and second semiconductor layers 112 and 114 of the fin stacks 110 and patterning the substrate 100 to form trenches in the substrate 100, and later an insulating material is filled into the trenches to form isolation structures 120 (as seen in FIG. 6). In some embodiments, the formation of the first or second semiconductor layer 112 or 114 may include one or more processes selected from chemical vapor deposition (CVD), atomic layer deposition (ALD), vapor phase epitaxy (VPE), molecular beam epitaxy (MBE), or the like. In some embodiments, the patterning may include one or more suitable etching processes, such as reactive ion etch (RIE), neutral beam etch (NBE), or a combination thereof. In some embodiments, the etching processes include anisotropic etching processes. In some embodiments, the isolation structures 120 are trench isolation structures and the insulating material filled in the trenches may include silicon oxide, silicon nitride, silicon carbon nitride (SiCN), silicon oxycarbon nitride (SiOCN), silicon germanium oxide or other suitable insulating materials.

It is understood that the alternating epitaxial growth processes are performed until a selected number of semiconductor sheets have been formed, and the number of the semiconductor sheets is not limited by the exemplary embodiments and figures provided herein. For example, the fin stack 110 may include six to twenty semiconductor sheets. Other numbers of semiconductor sheets can be utilized without departing from the scope of the present disclosure. In some embodiments, the semiconductor sheets are formed on the substrate 100 or over the substrate 100 with material layers there-between.

Referring to FIG. 1, dummy structures 120 (including the dummy structures 120-1, 120-2 and 120-3) are formed on the fin stack(s) 110. In some embodiments, each dummy structure 120 include a lining layer 121, a sacrificial material layer 122, a hard mask 123 and a cap mask 124 sequentially stacked from bottom to top. For example, the formation of the dummy structures 120 involves forming the lining layer 121 of an oxide material by thermal oxidation, forming the sacrificial material layer 122 by depositing a polysilicon layer, forming the hard mask 123 and the cap mask 124 by depositing a silicon nitride layer and a masking material, and then patterning the whole stack through photolithography and etching processes. In some embodiments, several parallel dummy structures are formed over and across over multiple parallel fin stacks, as the extending direction of the dummy structures is intersected with the extending direction of the fin stacks.

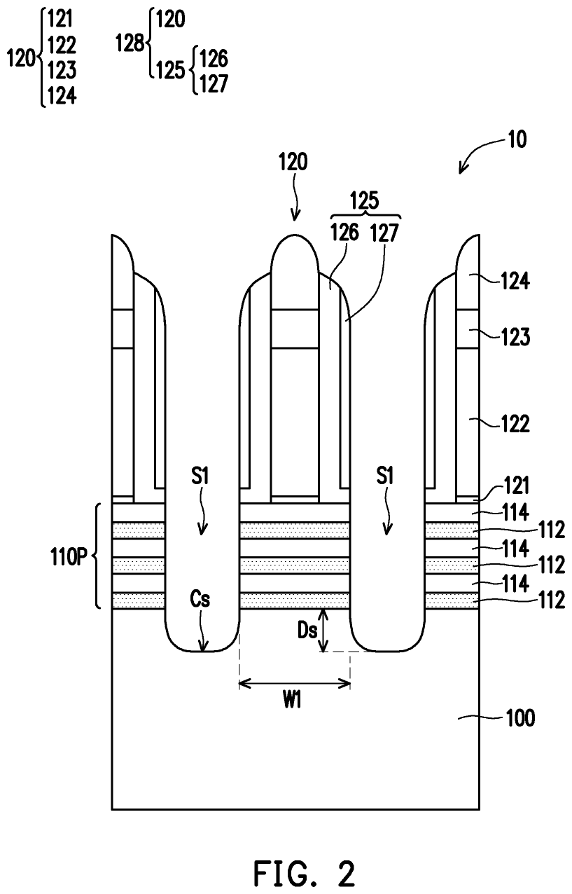

Referring to FIG. 2, sidewall spacers 125 along the sidewalls of the dummy structures 120 are formed. In some embodiments, the sidewall spacers 125 are formed by conformally depositing a first spacer material and then a second spacer material over the dummy structures 120 and then etching back the first and second spacer materials until the cap mask 124 is exposed. As seen in FIG. 2, the gate spacer(s) includes a double-layered structure of an inner spacer 126 and an outer spacer 127. In one embodiment, the material(s) of the sidewall spacers 125 include silicon nitride (SiN), silicon carbide (SiC), silicon carbonitride (SiCN) or silicon oxycarbon nitride (SiOCN). In one embodiment, the material(s) of the inner spacer(s) 126 of the sidewall spacers 125 include SiOCN, and the material(s) of the outer spacer 127 includes silicon nitride (SiN) or silicon carbide (SiC). In one embodiment, the material(s) of the inner spacer(s) 126 of the sidewall spacers 125 include SiOCN, and the material(s) of the outer spacer 127 includes SiOCN. In alternative embodiments, the sidewall spacers 125 may be single-layered structure or a three-layered structure or more layered structures. In some embodiments, as seen in FIG. 2, the composite structure 128 of the dummy structure 120 along with the sidewall spacers 125 located on the fin stack 110 has a width W1. In some embodiments, the composite structures 128 of the dummy structures 120 along with the spacers 125 are shown in the figures to have substantially vertical sidewalls.

In FIG. 2, using the composite structure 128 of the dummy structure 120 and the sidewall spacers 125 on the fin stacks 110 as the masks, the fin stacks 110 are patterned into the stacks 110P. That is, using the composite structure 128 of the dummy structure 120 and the sidewall spacers 125 as masks, the first semiconductor layers 112 and the second semiconductor layers 114 in the respective stacks 110 are etched. In some embodiments, the etching process includes one or more anisotropic etching processes. As the materials of the first semiconductor layers 112 and the second semiconductor layers 114 are different, the etching processes may include a series of etching processes using different etching recipes to have etch selectivity toward the predetermined materials. In some embodiments, during the patterning process, the fin stacks 110 are patterned into the patterned fin stacks 110P with openings S1 there-between, and the substrate 100 may be further etched to form cavities Cs in the substrate 100 with a depth Ds.

In embodiments, the stack(s) 110P has the substantially the same width W1 as the above composite structure 128 (the dummy structure 120 along with the sidewall spacers 125). In some embodiments, the patterned fin stacks 110P are shown in the figures to have substantially vertical sidewalls. When the pattern fin stacks 110P have substantially vertical sidewalls, the first semiconductor layers 112 and the second semiconductor layers 114 may have substantially the same length/width.

However, it is possible that the fin stacks 110 may have tapered sidewalls, such that a length/width of each of the first semiconductor layers 112 and the second semiconductor layers 114 may continuously increase in a direction towards the substrate 100.

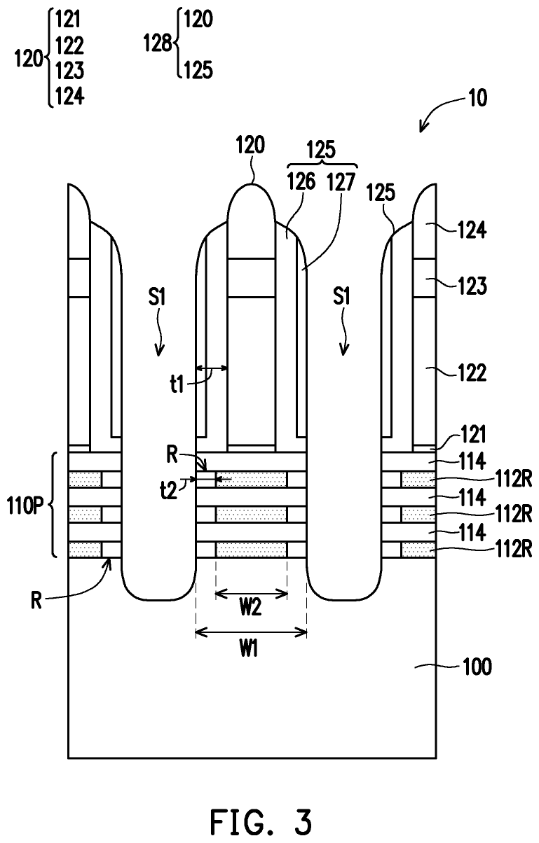

In FIG. 3, a lateral etching process is performed to the patterned fin stacks 110P through the openings S1, the first semiconductor layers 112 of the patterned fin stacks 110P are laterally etched to form recessed first semiconductor layers 112R with side recesses R. The formed recesses R are utilized to enable the formation of lateral spacers at opposite sides of the recessed first semiconductor layers 112R and between the second semiconductor layers 114. In FIG. 3, in some embodiments, the etching process has been performed to laterally recess the first semiconductor layers 112 (i.e. the sacrificial semiconductor layers), and the recesses first semiconductor layers 112R has a width W2 with respect to the second semiconductor layers 114. In some embodiments, the depth (lateral distance) of the recesses R is determined as half of the difference between the widths W1 and W2, as (W1−W2)/2. In some embodiments, the depth of the recesses R is smaller than the total thickness t1 of the sidewalls spacer(s) 125.

In some embodiments, the lateral etching process may include a wet etching process by using a chemical bath with etchant(s) that selectively etches the first semiconductor layers 112 (i.e. the sacrificial semiconductor layers) with respect to the second semiconductor layers 114. For example, the wet etching process is timed so that the first semiconductor layers 112 are recessed but not entirely removed. For certain specific etching processes such as the lateral etching process, due to high etch selectivity between the first semiconductor material(s) and the second semiconductor material(s), the first semiconductor layers 112 of the first semiconductor material may be etched or removed without significantly removing the second semiconductor layers 114 of the second semiconductor material. In some embodiments, the first semiconductor layers 112 are sacrificial layers that will later be removed, and the patterned second semiconductor layers 114 of the patterned stacks 110P are to form channel regions of the transistors. It is designed that there is high etch selectivity among the first and second semiconductor materials, so that one semiconductor material can be removed without significantly removing the other semiconductor material. In one embodiment, the first semiconductor layers 112 include SiGe, while the second semiconductor layers 114 include silicon. Such material difference allows the lateral etching process to recess the first semiconductor layers 112 to become the recessed first semiconductor layers 112R without significantly etching the second semiconductor layers 114.

In FIG. 3, in some embodiments, the remained second semiconductor layers 114, function as channel regions, have substantially the same width W1 (i.e. channel width) as the width W1 of the above composite structure 128. That is, the second semiconductor layers 114 of the stack(s) 110P has the channel width W1 larger than the width W2 of the recessed first semiconductor layers 112R.

Referring to FIG. 3, in some embodiments, lateral spacers 129 are formed in the recesses R at opposite sides of the recessed first semiconductor layers 112R and between the above and below second semiconductor layers 114. In some embodiments, the formation of the lateral spacers 129 includes depositing a spacer material such as silicon nitride by an ALD process, a CVD process, or other suitable processes into the recesses R and then performing at least one etching process to remove the extra spacer material by utilizing the sidewall spacers 125 as masks. In FIG. 3, the lateral spacers 129 are located directly below the sidewall spacers 125, and the outer sidewalls of the lateral spacers 129 and the sidewall spacers 125 are vertically aligned. In some embodiments, the thickness t1 of the sidewall spacer(s) 125 is larger than the thickness t2 of the lateral spacer(s) 129.

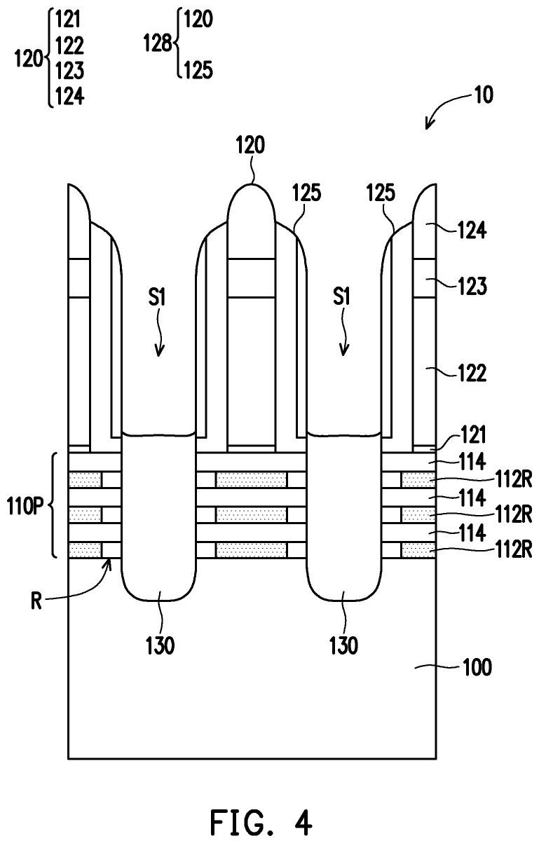

Referring to FIG. 4, source and drain regions 130 are formed within the openings S1 beside the stacks 110P and filling up the cavities Cs. In some embodiments, the source and drain regions 130 are epitaxy source and drain portions including crystalline materials exerting a tensile strain in the channel regions. In some embodiments, for N-type transistors, the source and drain regions 130 may include materials such as silicon, SiC, SiCP, SiP, or the like. In some embodiments, for P-type transistors, the source and drain regions 130 include materials such as SiGe, SiGeB, Ge, GeSn, or the like. The source and drain regions 130 may have facets and/or have surfaces raised from the top surfaces of the isolation structures 120 or substrate 100. In some embodiments, the source and drain regions 130 are grown epitaxially from the second semiconductor layers 114. In some embodiments, the source and drain regions 130 are epitaxially grown from the substrate 100. The source and drain regions 130 may be further doped with N-type dopants for N-type transistors. The source and drain regions 130 may be doped with P-type dopants for P-type transistors. The doping can be performed in-situ during the epitaxial growth. In some embodiments, the top surfaces of the source and drain regions 130 are slightly higher than the patterned fin stacks 110P (i.e. higher than the topmost second semiconductor layer 114).

Referring to FIG. 5 and FIG. 6, in some embodiments, an interlayer dielectric (ILD) layer 132 is formed over the substrate 100 covering the source and drain regions 130 and on the isolation structures 120. In some embodiments, the ILD layer 132 is formed within the openings S1 so that the ILD layer 132 covers the composite structures 128. In some embodiments, the ILD layer 132 at least covers the sidewall spacers 125 but exposes the dummy structures 120. In some embodiments, the ILD layer 132 includes more than one layers of dielectric materials, and the ILD layer 132 may include one or more layers of silicon oxide materials and one layer of silicon nitride as an etch stop layer. In some embodiments, the ILD layer 132 is formed by spin-coating, CVD, ALD, or other suitable deposition processes. Later, in some embodiments, a planarization process is performed to partially remove the ILD layer 132 and the composite structures 128. After the planarization process, as seen in FIG. 4, portions of the ILD layer 132, portions of the sidewall spacers 125 (i.e. part of the composite structure of inner spacers 126 and outer spacers 127) and portions of the dummy structures 120 (i.e. the hard mask 123, cap mask 124 and parts of the sacrificial material layer 122) are removed, and the remained structure has a coplanar top surface. As seen in FIG. 4, the sacrificial material layers 122 of the dummy structures 120 are exposed with the remained sidewall spacers 125 alongside and next to the exposed sacrificial material layers 122.

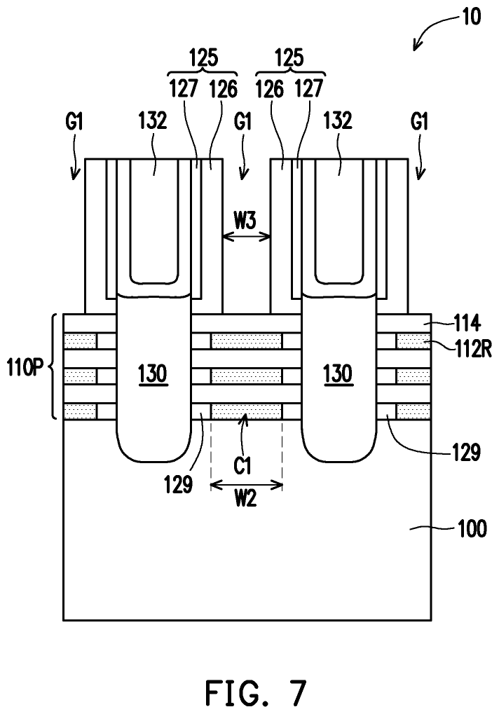

Referring to FIG. 7, in some embodiments, using the remained ILD layer 132 and the remained sidewall spacers 125 as masks, the exposed sacrificial material layers 122 in the dummy structures 120 are removed. In some embodiments, the lining layers 121 in the dummy structures 120 are also removed along with the removal of the sacrificial material layers 122. That is, the dummy structures 120 are removed. In some embodiments, at least one anisotropic etching process is performed to selectively etch off materials of the sacrificial material layer 122 and the lining layer 121 (the remained dummy structures 120) with respect to the materials of the sidewall spacers 125.

Referring to FIG. 7, in some embodiments, the removal of the exposed dummy structures 120 results in gate trenches G1 between the inner spacers 126 of the sidewall spacers 125. In some embodiments, in FIG. 7, the gate trench G1 defined by the inner sidewall of the inner spacer(s) 126 has a width W3 smaller than the width W2 of the recessed first semiconductor layers 112R.

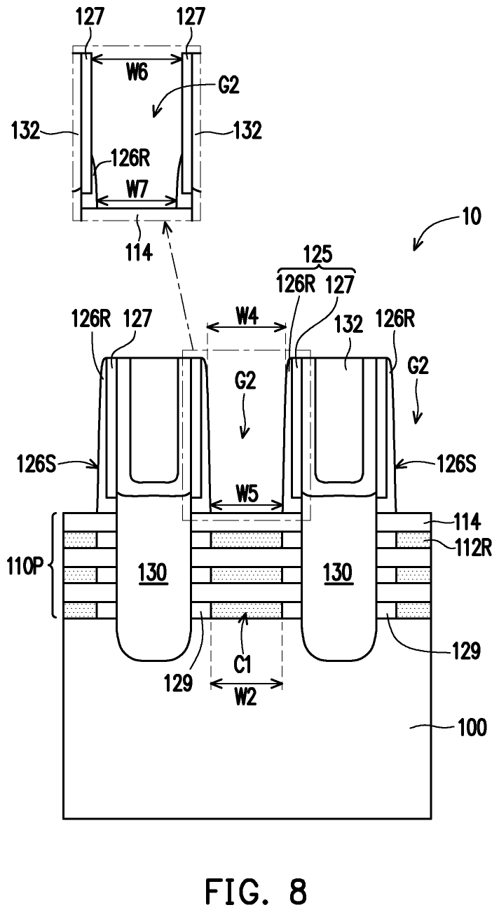

Referring to FIG. 8, a spacer etching process is performed to partially remove the remained sidewall spacers 125. In some embodiments, the spacer etching process includes at least one anisotropic etching process using one or more of fluoride-containing etchants such as NF₃, SF₆ and CF₄. In some embodiments, the spacer etching process is highly selective to etch the material(s) of the inner spacers 126 without removing the material(s) of the ILD layer 132 little or the first semiconductor material layers. In one embodiment, the spacer etching process includes a series of trimming etching processes using at least one etchant selected from NF₃, SF₆ and CF₄ along with carrier gases such as argon, nitrogen gas (N₂), and optionally oxygen gas (O₂) and hydrogen gas (H₂) under the temperature range of about 30-80 Celsius degrees. In one embodiment, the spacer etching process may include a cleaning process using deionized water or diluted HF.

In some embodiments, through the spacer etching process, the inner spacers 126 of the sidewall spacers 125 are partially removed, and the remained inner spacer(s) 126R has slant sidewalls as seen in FIG. 8. In some embodiments, after the spacer etching process, the remained inner spacers 126R have sloped sidewalls 126S and the gate trenches G1 are widened and become gate trenches G2. Each gate trench G2 corresponds to the location of a top gate electrode of the to-be-formed transistor(s). In some embodiments, the gate trenches G2 are slanting openings with a wider top opening of a width/dimension W4 and a narrow bottom of the width W5. In some embodiments, the remined inner spacers 126R are formed by removing the upper portions of the inner spacers 126 but the bottom portions of the inner spacers 126 are less removed. In some embodiments, the top width W4 of the widened gate trench G2 is larger than the bottom width W5, and the bottom width W5 is larger than the original width W3 and about the same as the width W2 of the recessed first semiconductor layers 112R. In one embodiment, relative to the original thickness of the inner spacers 126, the inner spacer 126R is thinned by at least about 35% of the original thickness. In one embodiment, the widened width W4 may be about 1.8 times to about 2 times of the width W3. In one embodiment, the original width W3 is about 7-8 nm, and the widened width W4 is about 13-17 nm.

In others embodiments, as seen in the enlarged view shown at the left of FIG. 8, after the spacer etching process, the gate trenches G1 are widened into gate trenches G2 and the inner spacers 126 become shorter and the remained inner spacers 126R are located at bottom portions of the outer spacers 127. As seen in the enlarged view shown at the left of FIG. 8, the sidewalls of the outer spacers 127 are partially exposed in the gate trenches G2. In some embodiments, the gate trenches G2 are slanting openings with a wider top opening of a width/dimension W6 and a narrow bottom of the width W7. In some embodiments, the remined inner spacers 126R having slant sidewalls are formed by completely removing the upper portions of the inner spacers 126 and partially removing the bottom portions of the inner spacers 126. In some embodiments, the top width W6 of the widened gate trench G2 is larger than the bottom width W7, and the bottom width W7 is larger than the original width W3 and the width W2 of the recessed first semiconductor layers 112R. In one embodiment, the widened width W6 may be about 1.9 times to about 2.1 times of the width W3.

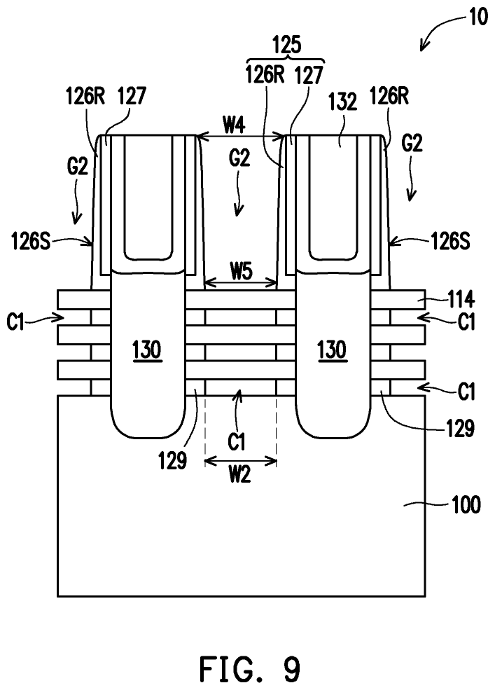

Referring to FIG. 9, in some embodiments, the recessed first semiconductor layers 112R are removed. Herein, the first semiconductor layers 112/112R are removed and replaced by later formed layers and may be referred to as replaceable semiconductor layers or sheets. In some embodiments, the recessed first semiconductor layers 112R are removed through performing a specific etching process selectively etching off the corresponding first semiconductor layers 112R with respect to the material of the lateral spacers 129. In some alternative embodiments, at least one anisotropic etching process may be performed to remove the recessed first semiconductor layers 112R.

Referring to FIG. 9, in some embodiments, the removal of the recessed first semiconductor layers 112R leaves cavities C1 between the second semiconductor layers 114. As the cavities C1 are formed by removing the recessed first semiconductor layers 112R, the cavities C1 have the same width W2. In some embodiments, in FIG. 9, the widened gate trench G2 has a maximum width W4 larger than the width W2 of the cavities C1, and a minimum width W4 equivalent to the width W2.

Based on the layout design, the gate trench(es) G2 and the below cavities C1 may be adjoining and contiguous with each other.

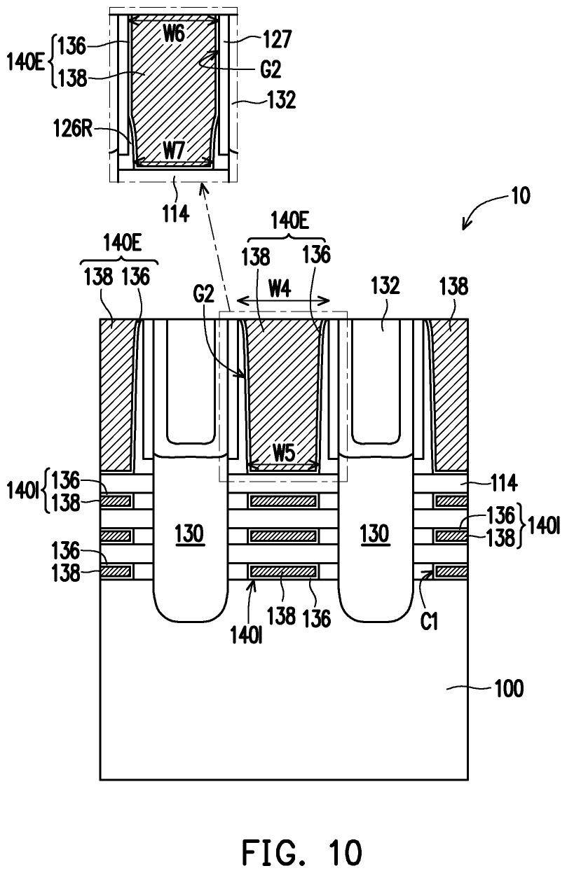

Referring to FIG. 10, in some embodiments, a high-k dielectric layer 136 is formed over the substrate 100 covering the ILD layer 132. In some embodiments, the high-k dielectric layer 136 conformally covers exposed surfaces of the gate trenches G2 and the cavities C1. In some embodiments, the high-k dielectric layer 136 is deposited directly on and all over the exposed surfaces of the gate trenches G2 and deposited directly on the exposed surfaces of the cavities C1. That is, the exposed surfaces of the second semiconductor layers (i.e. semiconductor nanosheets) 114 are fully covered by the high-k dielectric layer 136. In some embodiments, the second semiconductor layers 114 have the shape like sheets (with a larger dimension) and may be referred as nanosheets. In some embodiments, the second semiconductor layers 114 have the shape like wires (with a smaller dimension) and may be referred as nanowires.

Referring to FIG. 10, the second semiconductor layers 114, functioning as channel regions, are shaped as parallel sheets extending between the source and drain regions 130. In some embodiments, the high-k dielectric layer 136 formed directly on and all over the exposed surfaces of the gate trenches G2 is located directly on the sidewalls of the sidewall spacers 125. That is, the high-k dielectric layer 136 is located directly on the slant sidewalls 126S of the remained inner spacers 126R. Referring to FIG. 10, the high-k dielectric layer 136 formed directly on the exposed surfaces of the cavities C1 is located directly on the sidewalls of the lateral spacers 129. In some embodiments, the high-k dielectric layer 136 wraps around each of the second semiconductor layers 114.

In some embodiments, the high-k dielectric layer 136 corresponds to a gate dielectric layer of the transistor(s). The high-k dielectric layer 136 includes one or more layers of a high-k dielectric material, such as hafnium dioxide (HfO₂), HfSiO, HfSiON, HfTaO, HfSiO, HfZrO, zirconium oxide, aluminum oxide, titanium oxide, hafnium dioxide-alumina alloy, other suitable high-k dielectric materials, and/or combinations thereof. In some embodiments, the high-k dielectric layer 136 may be formed by CVD, ALD, or any suitable method. In one embodiment, the high-k dielectric layer 136 is formed using a highly conformal deposition process such as ALD in order to ensure the formation of a gate dielectric layer having a uniform thickness around each semiconductor nanosheet 114. It is understood that other materials and deposition processes may be used for the formation of the high-k dielectric layer 136, without departing from the scope of the present disclosure. In some embodiments, the gate dielectric layer 136 may include two or more sub-layers of different high-k dielectric materials such as sublayers of HfO₂ and ZrO.

Referring to FIG. 10, after forming the high-k dielectric layer 136, a first metallic layer 138 is formed on the high-k dielectric layer 136 filling into the gate trenches G2 and also filling into the cavities C1. Later, the extra high-k dielectric layer 136 and first metallic layer 138 are removed through a planarization process. As seen in FIG. 10, the top surfaces of the high-k dielectric layer 136 and first metallic layer 138 are substantially flush with and levelled with the top surfaces of the remained sidewall spacers 125, and substantially flush with and levelled with the top surface(s) of the ILD layer(s) 132.

In some embodiments, referring to FIG. 10, even though the gate trenches G2 are widened, the dimensions of the gate trenches G2 are rather small (in short channel regions), the first metallic layer 138 formed directly on the high-k dielectric layers 136 substantially fills up the trenches G2. In some embodiments, within the cavities C1, the first metallic layer 138 is formed directly on the high-k dielectric layers 136 and substantially fills up the cavities (or voids) between the second semiconductor layers 114.

In some embodiments, the first metallic layer 138 includes titanium (Ti), tungsten (W), vanadium (V), niobium (Nb), manganese (Mn), molybdenum (Mo), nitrides thereof or combinations thereof. In some embodiments, the first metallic layer 138 includes titanium nitride (TiN). In some embodiments, the first metallic layer 138 includes tungsten. For example, the first metallic layer 138 can be deposited using physical vapor deposition (PVD), ALD, CVD, or other suitable deposition processes. In some embodiments, the first metallic layer 138 includes a layer of titanium nitride (TiN) formed by CVD or ALD. In some embodiments, the first metallic layer 138 includes a layer of tungsten formed by PVD.

After the formation of the high-k dielectric layer 136 and the first metallic layer 138, the cavities C1 between the second semiconductor layers 114 in the sheet stacks 110P are filled and the trenches G2 are filled. In some embodiments, as seen in FIG. 10, the high-k dielectric layer 136 and the first metallic layer 138 filled in the cavities C1 function as the gate electrodes and are referred to as the lower gate electrodes or inner gates 140I, and the high-k dielectric layer 136 and the first metallic layer 138 filled in the trenches G2 also function as the gate electrodes and are referred to as top gate electrodes or outer gates 140E.

As seen in FIG. 10, in some embodiments, the profiles of the top gate electrode(s) 140E are conformal to the shapes of the trench(es) G2 with slant sidewalls, and the dimensions of the top gate electrode(s) 140E are decided by the dimensions of the trench(es) G2 with slant sidewalls. In some embodiments, the profiles of the lower gate electrode(s) 140I are conformal to the shapes of the cavities C1, and the dimensions of the lower gate electrodes 140E are decided by the dimensions of the cavities C1. In some embodiments, the top gate electrode(s) 140E has a top width W4 larger than the bottom width W5 of the top gate electrode(s) 140E, and the bottom width W5 of the top electrode(s) 140E is about the same as the width W2 of the lower gate electrodes 140I. In one embodiment, the width W4 may be about 1.3 times to about 1.5 times of the width W5.

In some embodiments, as seen in the enlarged view shown at the left of FIG. 10, the top width W6 of the top gate electrode 140E is larger than the bottom width W7 of the top gate electrode 140E, and the bottom width W7 is larger than the width W2 of the lower gate electrodes 140I. In one embodiment, the width W6 may be about 1.4 times to about 1.5 times of the width W7.

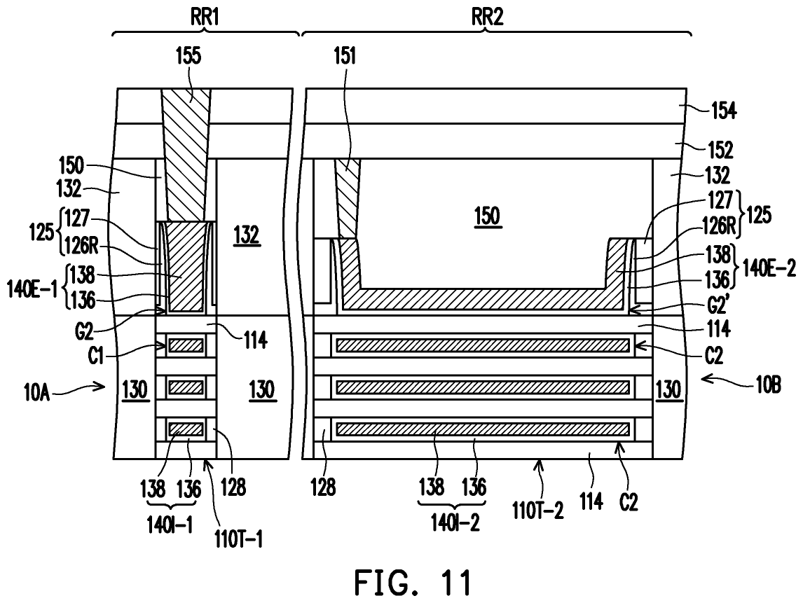

FIG. 11 illustrates a schematic cross-section view of portions of semiconductor devices in a first region RR1 and a second region RR2. In some embodiments, the first region RR1 and the second region RR2 may be spaced apart with other regions located there-between. In some embodiments, the first region RR1 and the second region RR2 are located in the device region, the first region RR1 is a high density region having devices of smaller critical dimensions and higher integration density, while the second region RR2 is a low density region having devices of larger critical dimensions and lower integration density. In some embodiments, the first region RR1 is a core region, while the second region RR2 is a peripheral region. In some embodiments, the first region RR1 may be referred to as a short channel region, while the second region RR2 may be referred to as a long channel region.

In some embodiments, the sheet stacks 110T include the sheet stack 110T-1 in the first region RR1 and the sheet stack 110T-2 in the second region RR2. In some embodiments, the sheet stack 110T-1 includes the second semiconductor layers 114 (i.e. channel sheets), lateral spacers 129 located between the second semiconductor layers 114, and the lower gate electrodes 140I-1 (the high-k dielectric layer 136 and the first metallic layer 138 wrapping around the semiconductor layers 114, filling the cavities C1 and located between the lateral spacers 129) in the first region RR1. In some embodiments, the sheet stack 110T-2 includes the second semiconductor layers 114 (i.e. channel sheets), lateral spacers 129 located between the second semiconductor layers 114, and the lower gate electrodes 140I-2 (the high-k dielectric layer 136 and the first metallic layer 138 wrapping around the semiconductor layers 114, filling the cavities C2 and located between the lateral spacers 129) in the second region RR2.

In some embodiments, top gate electrodes 140E-1 and 140E-2 are respectively formed inside the trenches G2 and G2′ in the first region RR1 and the second region RR2. In some embodiments, the top gate electrodes 140E-1 (including the high-k dielectric layer 136 and the first metallic layer 138) fills up the narrow trench G2 in the first region (short channel region) RR1, while the top electrode 140E-2 (including the high-k dielectric layer 136 and the first metallic layer 138) does not fill up the wide trench G2′ in the second region (long channel region) RR2. In some embodiments, the top electrode 140E-2 does not fill up the void trench G2′ but conformally extends along the profiles of the wide trench G2′.

In some embodiments, the gate electrodes 140I-1 and 140E-1 correspond to the gate electrodes of the short channel transistor(s) 10A in the first region RR1, and the gate electrodes 140I-2 and 140E-2 corresponds to the gate electrodes of the long channel transistor(s) 10B in the second region RR2. Although not explicit described herein, it is understood that the above described gate electrode structure may further include a liner layer, an interfacial layer, a work function layer, or a combination thereof.

Later, referring to FIG. 11, in some embodiments, an inter-dielectric layer 150 is formed over the transistors 10A and 10B covering the ILD layer 132, filling up the space and filling up the trenches G2′, and later contacts 151 (only one is shown) are formed in the inter-dielectric layer 150. The contact 151 formed in the inter-dielectric layer 150 is connected to the top gate electrode(s) 140E-2 in the second region RR2. In some embodiments, another inter-dielectric layer 152 and an insulating layer 154 are formed on the inter-dielectric layer 150. Later, in the first region RR1, at least one contact 155 is formed penetrating through the inter-dielectric layers 150 and 152 and the insulating layer 154, and the contact 155 connects to the top gate electrode 140E-1. In some embodiments, the inter-dielectric layer 150 or 152 includes silicon nitride, silicon oxynitride, silicon carbide or a combination thereof. It is understood that the inter-dielectric layer 150 or 152 may include one or more dielectric materials or one or more dielectric layers. In some embodiments, the inter-dielectric layer 150 or 152 is formed to a suitable thickness by CVD such as plasma enhanced CVD (PECVD), PVD, ALD or other suitable methods. For example, an interlayer dielectric material layer (not shown) may be formed by PECVD and an etching or polishing process may be performed to reduce the thickness of the interlayer dielectric material layer until a desirable thickness to form the inter-dielectric layer 150 or 152. In some embodiments, the inter-dielectric layer 150 or 152 includes silicon nitride, and the insulating layer 154 includes silicon oxide, or one or more low-k dielectric materials. Examples of low-k dielectric materials include silicate glass such as phospho-silicate-glass (PSG) and boro-phospho-silicate-glass (BPSG), BLACK DIAMOND®, SILK®, hydrogen silsesquioxane (HSQ), fluorinated silicon oxide (SiOF), amorphous fluorinated carbon, parylene, BCB (bis-benzocyclobutene), flare, or a combination thereof. In some embodiments, the insulating layer 154 is formed using flowable CVD (FCVD), PECVD, spin-on coating, or other suitable methods.

As seen in FIG. 11, the contact 151 and 155 are shown with slant sidewalls. It is understood that the contact openings may be formed with substantially vertical sidewalls if feasible, and the number of the contacts is merely exemplary but not intended for limiting the scope of this disclosure. In some embodiments, the contacts 151 and 155 are formed of one or more metallic materials such as tungsten, cobalt, titanium, aluminum, copper, tantalum, nitrides thereof or alloys thereof. Optionally, the extra metallic material may be removed by performing a planarization process, an etching process, or other suitable processes. In some embodiments, the planarization process may include performing a CMP process. As seen in FIG. 11, the top surface of the layer 150 is substantially flush with and levelled with the top surfaces of the contacts 151, and the top surface of the insulating layer 154 is substantially flush with and levelled with the top surface of the contact 155.

Referring to FIG. 11, the transistor 10A or 10B respectively in the regions RR1 or RR2 includes the semiconductor nanosheets 114 as the channel regions and the source and drain terminals 130 located at opposite sides of the semiconductor nanosheets 114. For the transistor 10A, the gate structure including the lower gate electrodes 140I-1 and the top gate electrode 140E-1 (composed of the high-k dielectric layers 136 and at least the metallic layer 138) wrapping around the channel regions (the semiconductor nanosheets) 114. For the transistor 10B, the gate structure including the lower gate electrodes 140I-2 and the top gate electrode 140E-2 (composed of the high-k dielectric layers 136 and at least the metallic layer 138) wrapping around the channel regions (the semiconductor nanosheets) 114. In some embodiments, the transistor 10A or 10B is referred to as a gate all around transistor.

In the illustrated embodiments, the described methods and structures may be formed compatible with the current semiconductor manufacturing processes. In exemplary embodiments, the described methods and structures are formed during front-end-of-line (FEOL) processes. The illustrated structure of transistor(s) 10, 10A, 10B may be a portion of integrated circuits. In some embodiments, the illustrated structure may include active devices such as thin film transistors, high voltage transistors, passive components, such as resistors, capacitors, inductors, fuses, and/or other suitable components. In some embodiments, additional steps may be provided before, during, and after the process steps depicted from FIG. 1 to FIG. 10, and some of the steps described above may be replaced or eliminated, for additional embodiments of the method.

As described above, the methods disclosed in the embodiments further includes performing a spacer etching process to widen the gate trenches so that the later formed outer gate electrodes inside the widened trench(es) have larger gate widths when compared with the gate width(s) of the inner gate electrodes formed inside the sheet stacks of the transistor structure. By doing so, the transistors can obtain satisfactory electrical properties.

Through performing a spacer etching process, the trench(es) are widened and the process window for forming the gate electrode layer becomes larger and uniform filling of the gate electrode material can be achieved, which improves the quality of the gate electrode and enhances the electrical performance of the transistors. Especially for the transistor(s) in the short channel region, the undesirable void or defects are not found in the gate electrode layer.

In some embodiments of the present disclosure, a semiconductor device structure is described. The semiconductor device structure including a semiconductor substrate, semiconductor channel sheets disposed over the semiconductor substrate, and source and drain regions located beside the semiconductor channel sheets. A gate structure is disposed between the source and drain regions and disposed over the semiconductor channel sheets. The gate structure laterally surrounds the semiconductor channel sheets. The gate structure includes a top gate electrode structure disposed above the semiconductor channel sheets, and lower gate electrode structures disposed between the semiconductor channel sheets. Sidewall spacers are disposed between the gate structure and source and drain regions, and the sidewall spacers located next to the top gate electrode structure have slant sidewalls.

In some embodiments of the present disclosure, a structure includes a substrate, first and second semiconductor channel sheets, source and drain regions, first and second gate structures and first and second sidewall spacers. The substrate has a first region and a second region. The first semiconductor channel sheets are disposed over the substrate and in the first region. The second semiconductor channel sheets are disposed over the substrate and in the second region. The first semiconductor channel sheets have a first channel width shorter than a second channel width of the second semiconductor channel sheets. The source and drain regions are located at opposite sides of the first semiconductor channel sheets and are located at opposite sides of the second semiconductor channel sheets. The first gate structure is disposed over the first semiconductor channel sheets and laterally surrounds the first semiconductor channel sheets. The first sidewall spacers are disposed between the first gate structure and the source and drain regions, and the first sidewall spacers have slant sidewalls. The second gate structure is disposed over the second semiconductor channel sheets and laterally surrounds the second semiconductor channel sheets. The second sidewall spacers are disposed between the second gate structure and the source and drain regions, and the second sidewall spacers have slant sidewalls.

In some embodiments of the present disclosure, a method for forming a semiconductor device is described. A semiconductor substrate is provided. A first stack having first semiconductor sheets and first replaceable semiconductor sheets in alternation is formed. A dummy structure is formed on the first stack. The dummy structure includes a dummy stack and sidewall spacers disposed on sidewalls of the dummy stack. The first stack is patterned using the dummy structure thereon as a mask. The dummy stack is removed to form a gate trench of a first width between the sidewall spacers. A spacer etching process is performed to narrow the sidewall spacers and widen the gate trench. The narrowed sidewall spacers have slant sidewalls. The first replaceable semiconductor sheets are removed to form cavities. A gate structure is formed filling into the widened gate trench covering the slant sidewalls and filling into the cavities.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a semiconductor substrate;
semiconductor channel sheets disposed over the semiconductor substrate;
source and drain regions, located beside the semiconductor channel sheets;
a gate structure, disposed between the source and drain regions and disposed over and laterally surrounding the semiconductor channel sheets, wherein the gate structure includes a top gate electrode structure disposed above the semiconductor channel sheets, and lower gate electrode structures disposed between the semiconductor channel sheets; and
sidewall spacers, disposed between the gate structure and source and drain regions;
wherein the sidewall spacers located next to the top gate electrode structure have slant sidewalls.

2. The structure of claim 1, wherein each of the sidewall spacers includes a first spacer and a second spacer disposed on the first spacer, and the first spacers have slant sidewalls, and the top gate electrode structure is in physical contact with the first spacers.

3. The structure of claim 2, wherein the gate structure includes a gate dielectric layer and a gate metallic layer, and the gate dielectric layer of the top gate electrode structure is in physical contact with the first spacers.

4. The structure of claim 1, wherein each of the sidewall spacers includes a first spacer and a second spacer disposed on the first spacer, and the first spacers have slant sidewalls, and the top gate electrode structure is in physical contact with the first spacers and the second spacers.

5. The structure of claim 4, wherein the gate structure includes a gate dielectric layer and a gate metallic layer, and the gate dielectric layer of the top gate electrode structure is in physical contact with the first spacers and the second spacers.

6. The structure of claim 1, wherein the top gate electrode structure has a first maximum width larger than a second maximum width of the lower gate electrode structures, and the semiconductor channel sheets have a channel width larger than the first maximum width.

7. The structure of claim 1, wherein the top gate electrode structure has a first maximum width substantially equivalent to a second maximum width of the lower gate electrode structures, and the semiconductor channel sheets have a channel width larger than the first maximum width and the second maximum width.

8. The structure of claim 1, further comprising an interlayer dielectric layer disposed beside the sidewall spacers and covering the source and drain regions, wherein the source and drain regions are epitaxy source and drain terminals.

9. The structure of claim 1, further comprising lateral inner spacers located between the lower gate electrode structures and the source and drain regions.

10. The structure of claim 1, wherein the semiconductor channel sheets include silicon or silicon germanium.

11. A structure, comprising:
a substrate having a first region and a second region;
first semiconductor channel sheets disposed over the substrate and in the first region;
second semiconductor channel sheets disposed over the substrate and in the second region, wherein the first semiconductor channel sheets have a first channel width shorter than a second channel width of the second semiconductor channel sheets;
source and drain regions, located at opposite sides of the first semiconductor channel sheets and at opposite sides of the second semiconductor channel sheets;
a first gate structure, disposed over and laterally surrounding the first semiconductor channel sheets;
first sidewall spacers disposed between the first gate structure and the source and drain regions, wherein the first sidewall spacers have slant sidewalls;
a second gate structure, disposed over and laterally surrounding the second semiconductor channel sheets; and
second sidewall spacers disposed between the second gate structure and the source and drain regions, wherein the second sidewall spacers have slant sidewalls.

12. The structure of claim 11, wherein each of the first sidewall spacers includes a first sub-spacer and a second sub-spacer disposed on the first sub-spacer, and the first sub-spacers have slant sidewalls.

13. The structure of claim 12, wherein the first gate structure that is located above the first semiconductor channel sheets is in physical contact with the slant sidewalls of the first sub-spacers.

14. The structure of claim 12, wherein the first gate structure that is located above the first semiconductor channel sheets is in physical contact with the slant sidewalls of the first sub-spacers and the second sub-spacers.

15. The structure of claim 11, wherein the first gate structure that is located above the first semiconductor channel sheets has a maximum width larger than that of the first gate structure that is located below the first semiconductor channel sheets.

16. The structure of claim 11, wherein the first gate structure that is located above the first semiconductor channel sheets has a maximum width substantially equivalent to that of the first gate structure that is located below the first semiconductor channel sheets.

17. A method for forming a semiconductor device, comprising:
providing a semiconductor substrate;
forming a first stack having first semiconductor sheets and first replaceable semiconductor sheets in alternation;
forming a dummy structure on the first stack, wherein the dummy structure includes a dummy stack and sidewall spacers disposed on sidewalls of the dummy stack;
patterning the first stack using the dummy structure thereon as a mask;
removing the dummy stack to form a gate trench of a first width between the sidewall spacers;
performing a spacer etching process to narrow the sidewall spacers and widen the gate trench, wherein the narrowed sidewall spacers have slant sidewalls;
removing the first replaceable semiconductor sheets to form cavities; and
forming a gate structure filling into the widened gate trench covering the slant sidewalls and filling into the cavities.

18. The method of claim 17, wherein forming a gate structure further comprises forming a gate dielectric layer and a metallic layer sequentially covering the gate dielectric layer and filling into the gate trench and the cavities.

19. The method of claim 17, wherein performing a spacer etching process includes performing an anisotropic etching process using fluoride-containing etchants.

20. The method of claim 19, wherein performing a spacer etching process further includes performing a wet cleaning process after performing the anisotropic etching process.
